(19) United States
(12) Patent Application Publication
(10) Pub. No.: US 2010/0269002 A1
(43) Pub. Date: Oct. 21, 2010

(54) Pseudo-Random Balanced Scan Burnin

(75) Inventor: Alessandro Paglieri, Richardson, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 12/427,671

(22) Filed: Apr. 21, 2009

(51) Int. Cl. G01R 31/28; G06F 11/22

(52) U.S. Cl. 714/728; 714/E11.148

(57) ABSTRACT

According to various illustrative embodiments, a method and system for toggling a scan enable signal are described. In one aspect, the method comprises setting a scanin seed and resetting a monitor, generating random shift patterns, and resetting the monitor a second time. The method also comprises generating the random shift patterns a second time and strobing an activity flag. The method also comprises resetting the monitor a third time and enabling the scan enable signal toggling mechanism, and generating random shift/capture patterns repeatedly at least a predetermined number of times.

### TECHNICAL FIELD OF THE PRESENT DISCLOSURE

The present disclosure relates generally to testing device circuitry and components. More particularly, the present disclosure describes a method and system useful for toggling a scan enable signal to improve the qualification process in built-in self-test burnin techniques that use pseudo-random pattern generation.

### BACKGROUND OF THE PRESENT DISCLOSURE

Burnin is widely used for device qualification. Conventional burnin techniques consist in activating most of the device by scan patterns. Scan patterns are much easier to generate than functional test patterns and have far better and measurable coverage of the device. However, conventional burnin techniques are deficient in the activation of application paths. This often leads to an improper qualification since the paths used in application mode are much less activated than the corresponding scan test paths.

More specifically, automated test pattern generation (ATPG) vectors are conventionally used for burnin tests. These ATPG vectors may give much higher and measurable coverage as compared to functional test patterns. With the ATPG vectors the coverage is toggle coverage. This toggle coverage may be measured using ATPG tools and/or simulators.

A scan burnin pattern is usually very similar to a stacked activation pattern. One difference is that scanout in the case of scan burnin patterns may be masked, similar to iddq patterns, without impacting the coverage. However, capture may not be eliminated as well. Capture coverage may be compared with shift coverage. At first sight, during shift all nodes are randomly toggling. The D and SD flop inputs toggle as well. However, consideration of the TD flop input muxing stage shows that, during shift, the p and n transistors of the D are not exercised at all, even if the gate is toggling, since Vds is zero because the source and drain are shorted out. Consequently, capture must be maintained.

The D inputs may be used in application mode. These D inputs are more important to “burn” than the SD inputs. Even if captures are not removed, these captures conventionally only occur once every many hundreds or thousands of shift cycles. This means that conventionally D transistors are “burned” much less than their corresponding SD transistors. In general, conventionally the D transistors are “burned” much less than the remaining combinatorial circuitry.

### SUMMARY OF THE PRESENT DISCLOSURE

According to various illustrative embodiments, a method and system for toggling a scan enable signal are described. In one aspect, the method comprises setting a scanin seed and resetting a monitor, generating random shift patterns, and resetting the monitor a second time. The method also comprises generating the random shift patterns a second time and strobing an activity flag. The method also comprises resetting the monitor a third time and enabling the scan enable signal toggling mechanism, and generating random shift/capture patterns repeatedly at least a predetermined number of times.

In another aspect, a method comprises setting a scanin seed and resetting a monitor, generating random shift patterns using at least one pseudo-random pattern generator as a random pattern generator for a scanin stream to a plurality of cores managed by a scan configuration module, and resetting the monitor a second time. The method also comprises generating the random shift patterns a second time and strobing an activity flag. The method also comprises resetting the monitor a third time and enabling the scan enable signal toggling mechanism, and generating random shift/capture patterns repeatedly at least a predetermined number of times to maintain a difference between scan activity and capture activity below a predetermined amount.

In yet another aspect, a system for toggling a scan enable signal is provided, the system comprising a scanin seed setter arranged to set a scanin seed and a monitor resetter arranged to reset a monitor at least three times. The system also comprises a random shift pattern generator arranged to generate random shift patterns at least twice. The system also comprises an activity flag strober arranged to strobe an activity flag. The system also comprises a scan enable signal toggling mechanism and an enabler arranged to enable the scan enable signal toggling mechanism. The system also comprises a random shift/capture pattern generator arranged to generate random shift/capture patterns repeatedly at least a predetermined number of times, wherein the system is arranged to execute a method comprising setting the scanin seed using the scanin seed setter and resetting the monitor using the monitor resetter. The method also comprises generating the random shift patterns using the random shift pattern generator. The method also comprises resetting the monitor a second time using the monitor resetter. The method also comprises generating the random shift patterns a second time using the random shift pattern generator. The method also comprises strobing an activity flag using the activity flag strober. The method also comprises resetting the monitor a third time using the monitor resetter and enabling the scan enable signal toggling mechanism using the enabler. The method also comprises generating random shift/capture patterns repeatedly at least a predetermined number of times using the random shift/capture pattern generator.

In various illustrative embodiments, capture and shift cycles may be looped closely, so that one may shift one cycle, then capture, then shift another cycles, then capture again, and so forth. The capture cycles may be split if there are balancing issues. In this way, the D transistors may be exercised substantially as often as the rest of the circuit. Burnin activity is substantially balanced.

### BRIEF DESCRIPTION OF THE DRAWINGS

The following figures form part of the present specification and are included to further demonstrate certain aspects of the present claimed subject matter, and should not be used to limit or define the present claimed subject matter. The present claimed subject matter may be better understood by reference to one or more of these drawings in combination with the description of embodiments presented herein. Consequently, a more complete understanding of the present embodiments and further features and advantages thereof may be acquired by referring to the following description taken in conjunction with the accompanying drawings, in which the leftmost significant digit(s) in the reference numerals denote(s) the first figure in which the respective reference numerals appear, wherein:

FIG. 1 schematically illustrates a particular example of various illustrative embodiments of a method in accord with the present disclosure;

FIG. 2 schematically illustrates another particular example of various illustrative embodiments of a timing diagram useful for a method in accord with the present disclosure;

FIG. 3 schematically illustrates another particular example of various illustrative embodiments of another timing diagram useful for a method in accord with the present disclosure;

FIG. 4 schematically illustrates another particular example of various illustrative embodiments of yet another timing diagram useful for a method in accord with the present disclosure;

FIG. 5 schematically illustrates a particular example of various illustrative embodiments of a system in accord with the present disclosure;

FIG. 6 schematically illustrates a particular example of various illustrative embodiments of another system in accord with the present disclosure;

FIG. 7 schematically illustrates a particular example of various illustrative embodiments of a component of a system in accord with the present disclosure;

FIG. 8 schematically illustrates a particular example of various illustrative embodiments of another component of a system in accord with the present disclosure;

FIG. 9 schematically illustrates a particular example of various illustrative embodiments of a component of a method in accord with the present disclosure; and

FIG. 10 schematically illustrates a particular example of various illustrative embodiments of another method in accord with the present disclosure.

It is to be noted, however, that the appended drawings illustrate only typical embodiments of the present claimed subject matter and are, therefore, not to be considered limiting of the scope of the present claimed subject matter, as the present claimed subject matter may admit to other equally effective embodiments.

### NOTATION AND NOMENCLATURE

Certain terms are used throughout the following description and claims to refer to particular system components and configurations. As one skilled in the art having the benefit of the present disclosure will appreciate, companies may refer to a component by different names. This document does not intend to distinguish between components that differ in name but not function. In the following discussion and in the claims, the terms “including” and “comprising” are used in an open-ended fashion, and, thus, should be interpreted to mean “including, but not limited to . . . ,” and so forth. Also, the term “couple” or “couples” is intended to mean either an indirect or direct electrical connection. Thus, if a first device couples to a second device, that connection may be through a direct electrical connection or though an indirect electrical connection via other devices and/or connections. Furthermore, the term “information” is intended to refer to any data, instructions, or control sequences that may be communicated between components of a device. For example, if information is sent between two components, data, instructions, control sequences, or any combination thereof may be sent between the two components.

### DETAILED DESCRIPTION OF ILLUSTRATIVE EMBODIMENTS

Illustrative embodiments of the present claimed subject matter are described in detail below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of the present disclosure.

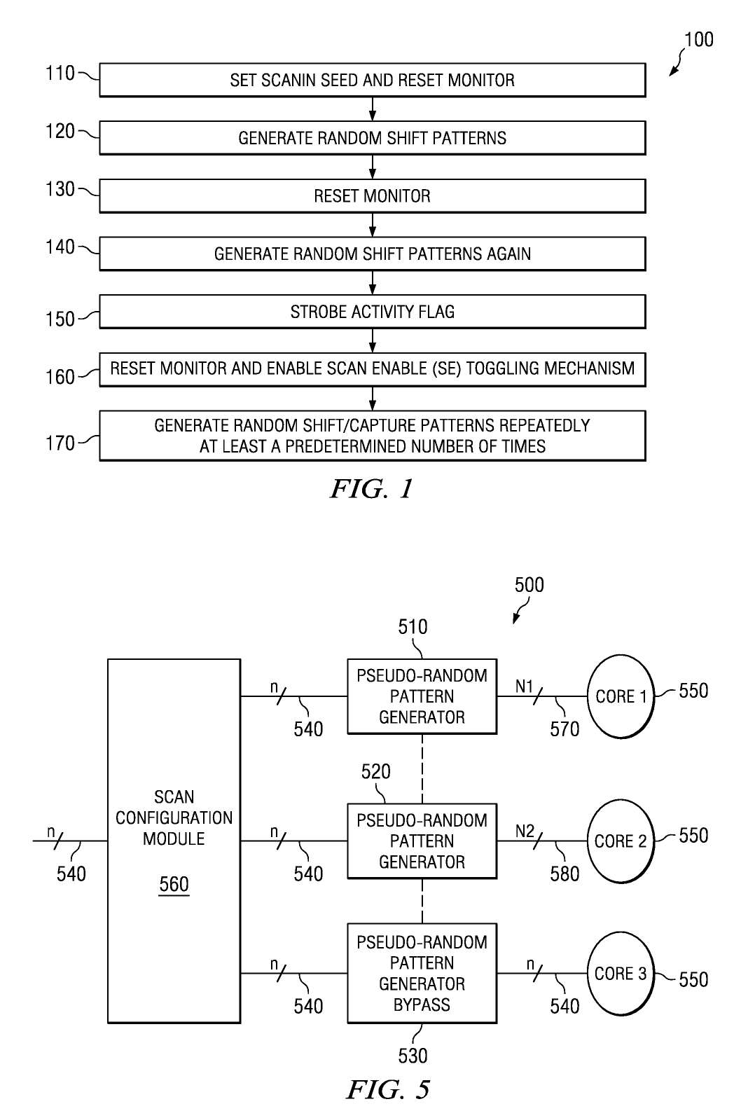

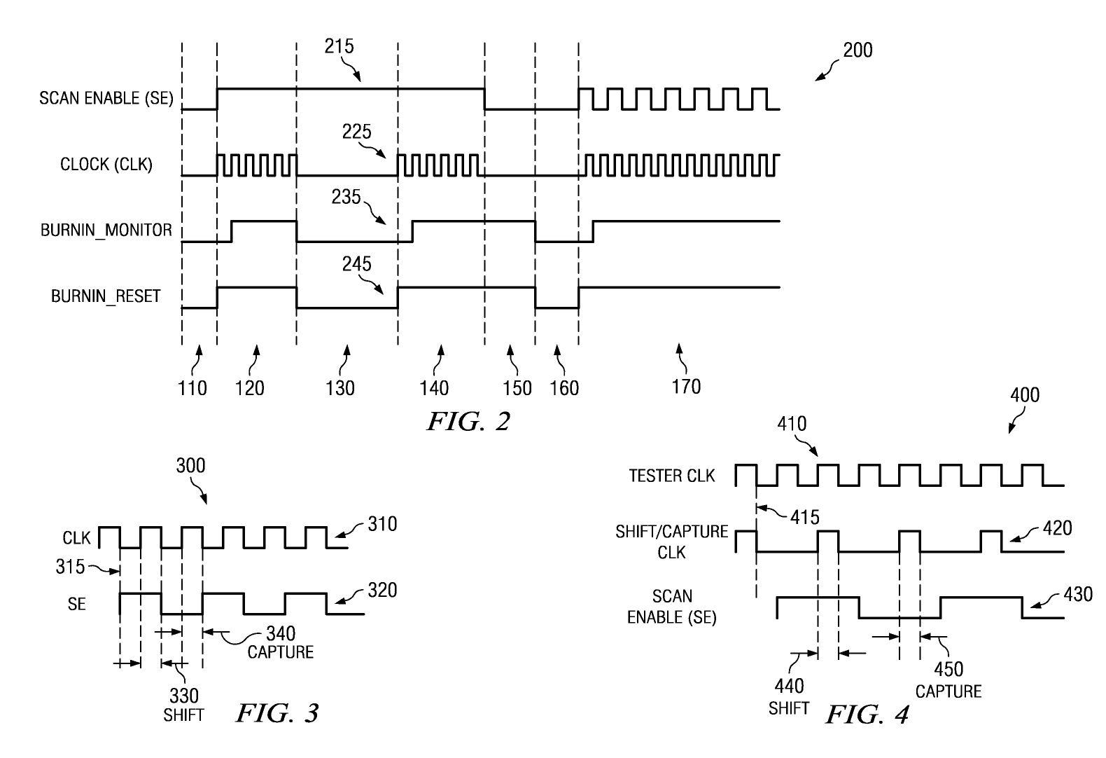

In various illustrative embodiments, as shown in FIG. 1 and FIG. 2, for example, a method 100 for toggling a scan enable signal 215 may comprise setting a scanin seed and resetting a monitor, as indicated at 110, generating random shift patterns, as indicated at 120, and resetting the monitor a second time, as indicated at 130. The method 100 may also comprise generating the random shift patterns a second time, as indicated at 140, and strobing an activity flag, as indicated at 150. The method 100 may also comprise resetting the monitor a third time and enabling the scan enable signal 215 toggling mechanism, as indicated at 160, and generating random shift/capture patterns repeatedly at least a predetermined number of times, as indicated at 170.

In various illustrative embodiments, as shown in FIG. 2, for example, a timing diagram 200 for the method 100 for toggling the scan enable signal 215 may comprise the scan enable (SE) signal 215, a clock (clk) signal 225, a burnin_monitor signal 235, and a burnin_reset signal 245. During the setting of the scanin seed and the resetting of the monitor, as indicated at 110, the scan enable (SE) signal 215, the clock (clk) signal 225, the burnin_monitor signal 235, and the burnin_reset signal 245 may all be low, at logical zero. During the generation of the random shift patterns, as indicated at 120, the scan enable (SE) signal 215 may be high, at logical one, the clock (clk) signal 225 may cycle between high and low, the burnin_monitor signal 235 may stay low for at least about one clock (clk) signal 225 cycle and then transition high, and the burnin_reset signal 245 may be high, at logical one. During the resetting of the monitor a second time, as indicated at 130, the scan enable (SE) signal 215 may stay high, at logical one, while the clock (clk) signal 225, the burnin_monitor signal 235, and the burnin_reset signal 245 may all be low, at logical zero.

During the generation of the random shift patterns a second time, as indicated at 140, the scan enable (SE) signal 215 may stay high, at logical one, the clock (clk) signal 225 may cycle between high and low, the burnin_monitor signal 235 may stay low for at least about one clock (clk) signal 225 cycle and then transition high, and the burnin_reset signal 245 may be high, at logical one. During the strobing of the activity flag, as indicated at 150, the scan enable (SE) signal 215 and the clock (clk) signal 225, may both be low, at logical zero, while the burnin_monitor signal 235, and the burnin_reset signal 245 may both be high, at logical one.

During the resetting of the monitor a third time and the enabling of the scan enable signal 215 toggling mechanism, as indicated at 160, the scan enable (SE) signal 215, the clock (clk) signal 225, the burnin_monitor signal 235, and the burnin_reset signal 245 may all be low, at logical zero. During the generation of random shift/capture patterns repeatedly at least a predetermined number of times, as indicated at 170, the scan enable (SE) signal 215 may toggle between high and low, staying high or low for about one clock (clk) signal 225 cycle, the clock (clk) signal 225 may cycle between high and low, the burnin_monitor signal 235 may stay low for at least about one clock (clk) signal 225 cycle and then transition high, and the burnin_reset signal 245 may be high, at logical one.

In various illustrative embodiments, generating the random shift/capture patterns repeatedly at least the predetermined number of times 170 may further comprise maintaining a difference between scan activity and capture activity below a predetermined amount. In these various illustrative embodiments, the predetermined amount may be about ten percent. In various illustrative embodiments, generating the random shift/capture patterns repeatedly at least the predetermined number of times 170 may further comprise having the predetermined number be about 20. In various illustrative embodiments, generating the random shift/capture patterns repeatedly at least the predetermined number of times 170 may further comprise enabling a capture activation density to be substantially similar to a shift activation density.

In various illustrative embodiments, as shown in FIG. 3, for example, enabling the scan enable signal toggling mechanism, as indicated at 160, may further comprise generating the scan enable signal 215, 320 internally and centrally, by a clock divider running on one of a falling edge 315 of a clock signal 310 and a rising edge of the clock signal 310, to be substantially skew insensitive. In these various illustrative embodiments, a shift 330 may occur when the scan enable signal 215, 320 is high while the clock signal 310 is also high. In these various illustrative embodiments, a capture 340 may occur when the scan enable signal 215, 320 is low while the clock signal 310 is high.

In various illustrative embodiments, as shown in FIG. 4, for example, enabling the scan enable signal toggling mechanism, as indicated at 160, may further comprise generating the scan enable signal 215, 430 centrally by gating a shift clock 420. In these various illustrative embodiments, a shift 440 may occur when the scan enable signal 215, 430 is high while the shift clock signal 420 is also high. In these various illustrative embodiments, a capture 450 may occur when the scan enable signal 215, 430 is low while the shift clock signal 420 is high. In these various illustrative embodiments, a tester clock signal 410 may or may not be synchronized with the shift clock signal 420.

In various illustrative embodiments, as shown in FIG. 5, for example, enabling the scan enable signal toggling mechanism, as indicated at 160, may further comprise generating the scan enable signal 215 in a distributed way into each of a plurality of cores 550 to be substantially skew-balanced with local scan chains in the plurality of the cores 550. In various illustrative embodiments, generating the random shift patterns 120, 140 may further comprise using pseudo-random pattern generators 510, 520 as random pattern generators for a scanin stream 540. In various illustrative embodiments, generating the random shift/capture patterns 170 may further comprise using pseudo-random pattern generators 510, 520 as random pattern generators. As described above in reference to FIG. 3, for example, a clock divider may be used on a clock signal 310 to make the scan enable signal 215, 320 toggle to reproduce the random pattern. Scan inputs only need to be tied to a fixed “seed” for pseudo-random pattern generators 510, 520. Scan outputs may be masked.

Scan outputs may be monitored for activity. An edge detector may be used over a certain window and on all scanouts to generate a stable flag. A special double shift sequence without capture must be used to detect chain stucks. This will ensure that scanning is going on regardless of the actual pattern. This monitor has to be reset and/or enabled regularly over the implementation in the test device language. In various illustrative embodiments, as shown in FIG. 1 and FIG. 2, for example, the method 100 for toggling a scan enable signal 215 may be programmed in the burnin test device language as follows: (1) SETR to set the scanin seed and reset the monitor, as indicated at 110; (2) RUNP to generate the random shift patterns, as indicated at 120; (3) SETR to reset the monitor a second time, as indicated at 130; (4) RUNP to generate the random shift patterns a second time, as indicated at 140, where this second shift in a row assures stucks are eventually detected by the monitor; (5) SETR to strobe the activity flag, as indicated at 150; SETR to reset the monitor a third time and enable the scan enable signal 215 toggling mechanism, as indicated at 160; and (7) RUNP to generate the random shift/capture patterns repeatedly at least a predetermined number of times, as indicated at 170, which needs to be repeated at least about 20 times to maintain the difference between scan activity and capture activity below about 10%.

In various illustrative embodiments, as shown in FIG. 5, for example, a system 500 useful with the toggling of the scan enable signal 215 may comprise one or more pseudo-random pattern generators 510, 520 coupled between one or more cores 550 (illustrated by Core 1, Core 2, and Core 3 in FIG. 5) and a scan configuration module 560. The scan configuration module 560 may be arranged to configure scan chains to test one or more of the cores 550. In various illustrative embodiments, each of the pseudo-random pattern generators 510, 520 may be bypassed, as indicated at 530.

In various illustrative embodiments, an n-bit scanin stream 540 may be input into the scan configuration module 560 and then may be output appropriately to one or more of the pseudo-random pattern generators 510, 520 and/or one or more of the pseudo-random pattern generators bypasses 530. The n-bit scanin stream 540 input into the pseudo-random pattern generator 510 may be output as an N1-bit scan chain 570 and input to one or more of the cores 550, such as Core 1, as shown in FIG. 5. The n-bit scanin stream 540 input into the pseudo-random pattern generator 520 may be output as an N2-bit scan chain 580 and input to one or more of the cores 550, such as Core 2, as shown in FIG. 5. In various illustrative embodiments, N1 and/or N2 may be larger than n. In various illustrative embodiments, N1 and/or N2 may be much larger than n if the pseudo-random pattern generation 510, 520 is part of an already existing scan compression/decompression tool, such as the MGC Test Kompress. The n-bit scanin stream 540 input into the pseudo-random pattern generator bypass 530 may be output as an n-bit scan chain and input to one or more of the cores 550, such as Core 3, as shown in FIG. 5.

In various illustrative embodiments, as shown in FIG. 5, for example, the devices may comprise multiple cores 550. These cores 550 may or may not be subjected to pseudo-random pattern generators 510, 520, in the same way as for the top/core level. Existing scan compression/built-in self-test tools may be reused if they provide this pseudo-random pattern generator 510, 520 capability. All cores 550 may be managed by the scan configuration module (SCM) 560. The cores 550 may be individually selected for an ATPG run or even chained for the full chip iddq mode. Usually, when chained, the pseudo-random pattern generators 510, 520 are put in bypass mode.

However, for burnin purposes according to the present disclosure, the cores 550 may be chained for the full chip iddq mode without setting the pseudo-random pattern generation bypass 530. The pseudo-random pattern generation burnin strategy described herein applies as well to such as configuration. Each pseudo-random pattern generator 510, 520 may generate a pseudo-random scan stream from a tied input at the front of the chain or from a previous core 550 scanout from a core 550 subjected to pseudo-random pattern generation by pseudo-random pattern generators 510, 520. Provided that cores 550 not subjected to pseudo-random pattern generation by pseudo-random pattern generators 510, 520 are not at the front of the chain, the cores 550 not subjected to pseudo-random pattern generation by pseudo-random pattern generators 510, 520 may also shift the random stream provided by a previous core 550 scanout port from a core 550 subjected to pseudo-random pattern generation by pseudo-random pattern generators 510, 520.

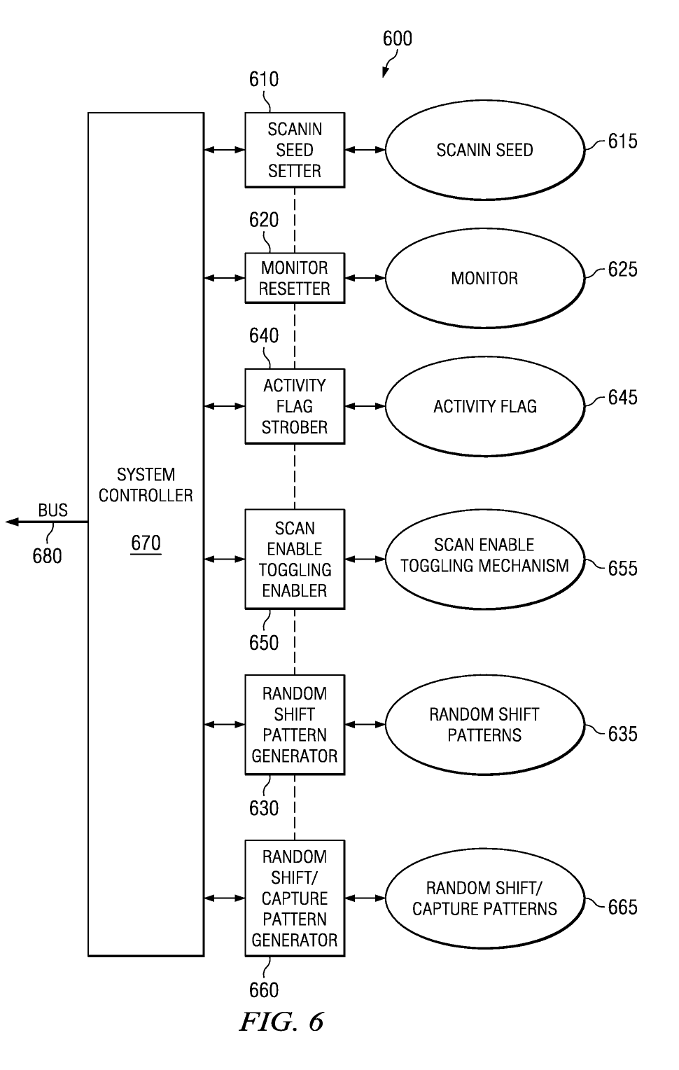

In various illustrative embodiments, as shown in FIG. 6, for example, a system 600 for toggling the scan enable signal 215 may comprise a scanin seed setter 610 arranged to set a scanin seed 615 and a monitor resetter 620 arranged to reset a monitor 625 at least three times, a random shift pattern generator 630 arranged to generate random shift patterns 635 at least twice, an activity flag strober 640 arranged to strobe an activity flag 645, a scan enable signal toggling mechanism 655 and an enabler 650 arranged to enable the scan enable signal toggling mechanism 655, and a random shift/capture pattern generator 660 arranged to generate random shift/capture patterns 665 repeatedly at least a predetermined number of times. The system 600 may be arranged to execute the method 100 by setting the scanin seed 615 using the scanin seed setter 610 and resetting the monitor 625 using the monitor resetter 620, as indicated at 110, generating the random shift patterns 635 using the random shift pattern generator 630, as indicated at 120, resetting the monitor 625 a second time using the monitor resetter 620, as indicated at 130, and generating the random shift patterns 635 a second time using the random shift pattern generator 630, as indicated at 140. The system 600 may further be arranged to execute the method 100 by strobing an activity flag 645 using the activity flag strobe 640, as indicated at 150, resetting the monitor 625 a third time using the monitor resetter 630 and enabling the scan enable signal toggling mechanism 655 using the enabler 650, as indicated at 160, and generating random shift/capture patterns 665 repeatedly at least a predetermined number of times using the random shift/capture pattern generator 660, as indicated at 170.

The system 600 may further comprise a system controller 670 arranged to control the system 600 to execute the method 100. The system 600 may be coupled to other components of an information processing system (not shown) through bus 680.

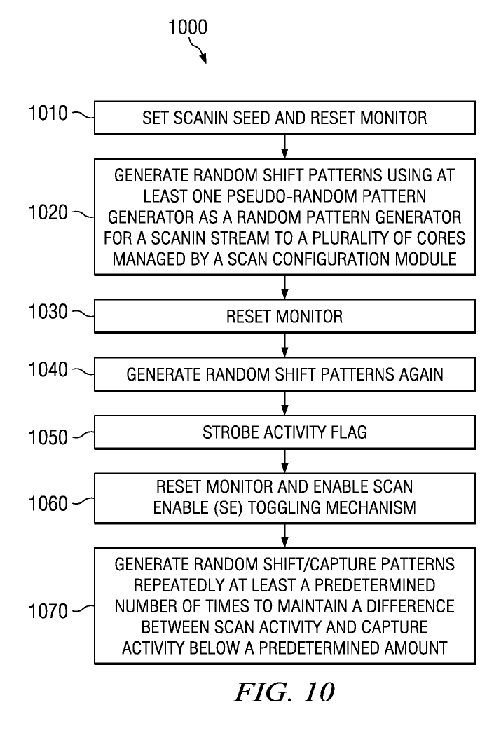

In various illustrative embodiments, as shown in FIG. 10, FIG. 2, and FIG. 5, for example, a method 1000 for toggling a scan enable signal 215 may comprise setting a scanin seed and resetting a monitor, as indicated at 1010, generating random shift patterns using pseudo-random pattern generators 510, 520 as a random pattern generator for a scanin stream 570, 580 to a plurality of cores 550 managed by a scan configuration module 560, as indicated at 1020, and resetting the monitor a second time, as indicated at 1030. The method 1000 may also comprise generating the random shift patterns a second time, as indicated at 1040, and strobing an activity flag, as indicated at 1050. The method 1000 may also comprise resetting the monitor a third time and enabling the scan enable signal 215 toggling mechanism, as indicated at 1060, and generating random shift/capture patterns repeatedly at least a predetermined number of times to maintain a difference between scan activity and capture activity below a predetermined amount, as indicated at 1070. The system 600 may further comprise the system controller 670 arranged to control the system 600 to execute the method 1000.

In various illustrative embodiments, the scan configuration module 560 chains the plurality of cores 550 in an iddq mode without setting a pseudo-random pattern generator bypass 530. In various illustrative embodiments, each pseudo-random pattern generator 510, 520 in a chain generates a pseudo-random scan stream 570, 580 from one of a tied input at the front of the chain and a previous pseudo-random pattern generated core 550 scanout, where the core 550 scanout is generated by pseudo-random pattern generators 510, 520. In various illustrative embodiments, the cores 550 without a pseudo-random pattern generator 510, 520 input also shift a pseudo-random stream provided by a previous pseudo-random pattern core 550 scanout port, where the pseudo-random pattern core 550 scanout is generated by generators 510, 520. In various illustrative embodiments, setting the scanin seed 1010 may further comprise setting a plurality of scanin seeds and concatenating multiple scan enable signal 215 togglings. Implementations of the test device language must be fault-simulated for toggle coverage. For example, Modelsim with toggle add and report commands may be used, with no simulated design flow required. If higher coverage is needed, multiple implementations of the test device language with different “seeds” may be concatenated.

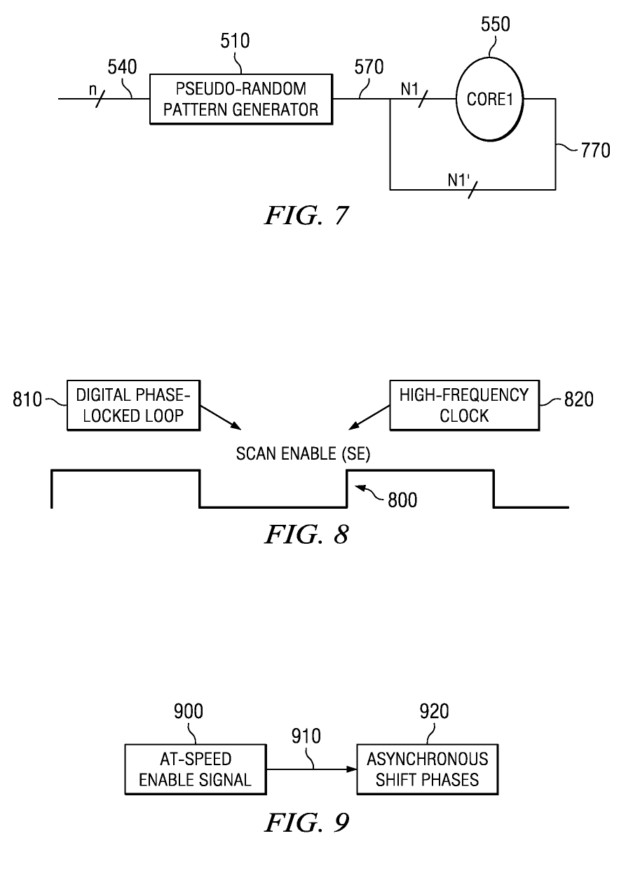

In various illustrative embodiments, as shown in FIG. 7, for example, at least one scanout channel 770 may be looped into at least one scanin channel 570. The n-bit scanin stream 540 may be input into the pseudo-random pattern generator 510 and may be output as an N1-bit scanin channel 570 and input to one or more of the cores 550, such as Core 1, whose N1′-bit scanout channel 770 may be looped into the scanin channel 570, as shown in FIG. 7, where N1′ may be larger than, smaller than, or equal to N1. Looping scanout channels 770 into scanin channels 570 may help in reaching high coverage faster by having greater “pseudo-randomness,” for example.

In various illustrative embodiments, the scan enable signal 430 toggling may be substantially asynchronous with the tester clock signal 410. In these various illustrative embodiments, the pseudo-random pattern generation burnin techniques described herein may not require any synchronization during shift/capture phases with the tester clock signal 410, since scan inputs are tied to a “seed” value and the capture/shift toggling mechanism just needs the shift/capture clock signal 420 to generate the scan enable signal 430 toggling. In various illustrative embodiments, as shown in FIG. 8, for example, the scan enable signal 800 toggling may be generated by either a digital phase-locked-loop 810 or an external high-frequency clock 820. In various illustrative embodiments, as shown in FIG. 9, for example, an at-speed enable signal 900 is provided to trigger 910 asynchronous shift phases 920.

In various illustrative embodiments, built-in self-test techniques such as using pseudo-random pattern generators 510, 520 for pseudo-random scan pattern generation with specific circuitry may also generate the scan enable (SE) signal 215. This scan enable (SE) signal 215 may be the discriminator between scan chain shift and capture phases. If on-chip generated and because of pseudo-randomness of patterns, this scan enable (SE) signal 215 may toggle every other shift clock. Different ways of implementing this scan enable (SE) signal 215 toggling, as described herein, may be used to solve different design constraints. One of the basic concepts is that this scan enable (SE) signal 215 toggling may enable the capture activation density to be substantially equivalent to the shift activation density. This results in substantially balanced activation of scan and application paths to scan flip-flops, resulting in a far better and more reliable qualification process.

According to various illustrative embodiments, a method and system for toggling a scan enable signal are described. In one aspect, the method comprises setting a scanin seed and resetting a monitor, generating random shift patterns, and resetting the monitor a second time. The method also comprises generating the random shift patterns a second time and strobing an activity flag. The method also comprises resetting the monitor a third time and enabling the scan enable signal toggling mechanism, and generating random shift/capture patterns repeatedly at least a predetermined number of times.

In various aspects, the method further comprises generating the random shift/capture patterns repeatedly at least the predetermined number of times further comprising maintaining a difference between scan activity and capture activity below a predetermined amount. This method further comprises the predetermined amount being about ten percent. In various aspects, the method further comprises the predetermined number being about 20. In various aspects, the method further comprises generating the random shift/capture patterns repeatedly at least the predetermined number of times further comprising enabling a capture activation density to be substantially similar to a shift activation density.

In various aspects, the method further comprises enabling the scan enable signal toggling mechanism further comprising generating the scan enable signal internally and centrally by a clock divider running on one of a falling edge of a clock signal and a rising edge of the clock signal to be substantially skew insensitive. In various aspects, the method further comprises enabling the scan enable signal toggling mechanism further comprising generating the scan enable signal in a distributed way into each of a plurality of cores to be substantially skew balanced with local scan chains in the plurality of the cores. In various aspects, the method further comprises enabling the scan enable signal toggling mechanism further comprising generating the scan enable signal centrally by gating a shift clock.

In various aspects, the method further comprises generating the random shift patterns further comprising using pseudo-random pattern generation as a random pattern generator for a scanin stream.

In various aspects, the method further comprises generating the random shift/capture patterns further comprising using pseudo-random pattern generation as a random pattern generator.

In another aspect, a method for toggling a scan enable signal comprises setting a scanin seed and resetting a monitor, generating random shift patterns using pseudo-random pattern generation as a random pattern generator for a scanin stream to a plurality of cores managed by a scan configuration module, and resetting the monitor a second time. The method also comprises generating the random shift patterns a second time and strobing an activity flag. The method also comprises resetting the monitor a third time and enabling the scan enable signal toggling mechanism, and generating random shift/capture patterns repeatedly at least a predetermined number of times to maintain a difference between scan activity and capture activity below a predetermined amount.

In various aspects, the method further comprises the scan configuration module chaining the plurality of cores in an iddq mode without setting a pseudo-random pattern generator bypass. This method further comprises each pseudo-random pattern generator in a chain generating a pseudo-random scan stream from one of a tied input at the front of the chain and a previous pseudo-random pattern generated core scanout.

In various aspects, the method further comprises cores without a pseudo-random pattern generator input also shifting a pseudo-random stream provided by a previous pseudo-random pattern generated core scanout port. In various aspects, the method further comprises setting the scanin seed further comprising setting a plurality of scanin seeds and concatenating multiple scan enable signal togglings. In various aspects, the method further comprises at least one scanout channel being looped into at least one scanin channel.

In various aspects, the method further comprises the scan enable signal toggling being substantially asynchronous with a tester signal. In various aspects, the method further comprises the scan enable signal toggling being generated by one of a digital phase-locked-loop and an external high-frequency clock. In various aspects, the method further comprises an at-speed enable signal being provided to trigger asynchronous shift phases.

In yet another aspect, a system for toggling a scan enable signal is provided, the system comprising a scanin seed setter arranged to set a scanin seed and a monitor resetter arranged to reset a monitor at least three times. The system also comprises a random shift pattern generator arranged to generate random shift patterns at least twice. The system also comprises an activity flag strober arranged to strobe an activity flag. The system also comprises a scan enable signal toggling mechanism and an enabler arranged to enable the scan enable signal toggling mechanism. The system also comprises a random shift/capture pattern generator arranged to generate random shift/capture patterns repeatedly at least a predetermined number of times, wherein the system is arranged to execute a method comprising setting the scanin seed using the scanin seed setter and resetting the monitor using the monitor resetter. The method also comprises generating the random shift patterns using the random shift pattern generator. The method also comprises resetting the monitor a second time using the monitor resetter. The method also comprises generating the random shift patterns a second time using the random shift pattern generator. The method also comprises strobing an activity flag using the activity flag strober. The method also comprises resetting the monitor a third time using the monitor resetter and enabling the scan enable signal toggling mechanism using the enabler. The method also comprises generating random shift/capture patterns repeatedly at least a predetermined number of times using the random shift/capture pattern generator.

In accordance with the present disclosure, an apparatus, system, and method useful for toggling a scan enable signal are disclosed. In various aspects, an apparatus in accordance with the present disclosure may comprise means for toggling a scan enable signal and means for enabling the means for toggling the scan enable signal, both the means for toggling the scan enable signal and the means for enabling the means for toggling the scan enable signal covering corresponding structures and/or materials described herein and equivalents thereof.

In various other aspects, a system in accordance with the present disclosure may comprise means for toggling a scan enable signal, means for enabling the means for toggling the scan enable signal, and means for using the means for toggling the scan enable signal, all of the means for toggling the scan enable signal, the means for enabling the means for toggling the scan enable signal, and the means for using the means for toggling the scan enable signal covering corresponding structures and/or materials described herein and equivalents thereof. In yet various other aspects, a method in accordance with the present disclosure may comprise steps for toggling a scan enable signal and steps for enabling the steps for toggling the scan enable signal, both the steps for toggling the scan enable signal and the steps for enabling the steps for toggling the scan enable signal covering corresponding acts described herein and equivalents thereof.

The particular embodiments disclosed above are illustrative only, as the present claimed subject matter may be modified and practiced in different but equivalent manners apparent to those skilled in the art having the benefit of the teachings herein. Furthermore, no limitations are intended to the details of construction or design herein shown, other than as described in the claims below. It is therefore evident that the particular illustrative embodiments disclosed above may be altered or modified and all such variations are considered within the scope and spirit of the present claimed subject matter. In particular, every range of values (of the form, “from about a to about b,” or, equivalently, “from approximately a to b,” or, equivalently, “from approximately a-b”) disclosed herein is to be understood as referring to the power set (the set of all subsets) of the respective range of values, in the sense of Georg Cantor. Accordingly, the protection sought herein is as set forth in the claims below.

What is claimed is:

1. A method for toggling a scan enable signal, the method comprising:
setting a scanin seed and resetting a monitor;
generating random shift patterns;
resetting the monitor a second time;
generating the random shift patterns a second time;
strobing an activity flag;
resetting the monitor a third time and enabling the scan enable signal toggling mechanism; and
generating random shift/capture patterns repeatedly at least a predetermined number of times.

2. The method of claim 1, wherein generating the random shift/capture patterns repeatedly at least the predetermined number of times further comprises maintaining a difference between scan activity and capture activity below a predetermined amount.

3. The method of claim 2, wherein the predetermined amount is about ten percent.

4. The method of claim 1, wherein the predetermined number is about 20.

5. The method of claim 1, wherein generating the random shift/capture patterns repeatedly at least the predetermined number of times further comprises enabling a capture activation density to be substantially similar to a shift activation density.

6. The method of claim 1, wherein enabling the scan enable signal toggling mechanism further comprises generating the scan enable signal internally and centrally by a clock divider running on one of a falling edge of a clock signal and a rising edge of the clock signal to be substantially skew insensitive.

7. The method of claim 1, wherein enabling the scan enable signal toggling mechanism further comprises generating the scan enable signal in a distributed way into each of a plurality of cores to be substantially skew balanced with local scan chains in the plurality of the cores.

8. The method of claim 1, wherein enabling the scan enable signal toggling mechanism further comprises generating the scan enable signal centrally by gating a shift clock.

9. The method of claim 1, wherein generating the random shift patterns further comprises using pseudo-random pattern generation as a random pattern generator for a scanin stream.

10. The method of claim 1, wherein generating the random shift/capture patterns further comprises using pseudo-random pattern generation as a random pattern generator.

11. A method for toggling a scan enable signal, the method comprising:
setting a scanin seed and resetting a monitor;
generating random shift patterns using at least one pseudo-random pattern generator as a random pattern generator for a scanin stream to a plurality of cores managed by a scan configuration module;
resetting the monitor a second time;
generating the random shift patterns a second time;
strobing an activity flag;
resetting the monitor a third time and enabling the scan enable signal toggling mechanism; and
generating random shift/capture patterns repeatedly at least a predetermined number of times to maintain a difference between scan activity and capture activity below a predetermined amount.

12. The method of claim 11, wherein the scan configuration module chains the plurality of cores in an iddq mode without setting a pseudo-random pattern generator bypass.

13. The method of claim 12, wherein each pseudo-random pattern generator in a chain generates a pseudo-random scan stream from one of a tied input at the front of the chain and a previous pseudo-random pattern generated core scanout.

14. The method of claim 11, wherein cores without a pseudo-random pattern generator input also shift a pseudo-random stream provided by a previous pseudo-random pattern generated core scanout port.

15. The method of claim 11, wherein setting the scanin seed further comprises setting a plurality of scanin seeds and concatenating multiple scan enable signal togglings.

16. The method of claim 11, wherein at least one scanout channel is looped into at least one scanin channel.

17. The method of claim 11, wherein the scan enable signal toggling is substantially asynchronous with a tester signal.

18. The method of claim 17, wherein the scan enable signal toggling is generated by one of a digital phase-locked-loop and an external high-frequency clock.

19. The method of claim 18, wherein an at-speed enable signal is provided to trigger asynchronous shift phases.

20. A system for toggling a scan enable signal, the system comprising:
a scanin seed setter arranged to set a scanin seed and a monitor resetter arranged to reset a monitor at least three times;
a random shift pattern generator arranged to generate random shift patterns at least twice;
an activity flag strober arranged to strobe an activity flag;
a scan enable signal toggling mechanism and an enabler arranged to enable the scan enable signal toggling mechanism; and
a random shift/capture pattern generator arranged to generate random shift/capture patterns repeatedly at least a predetermined number of times, wherein the system is arranged to execute a method comprising:
setting the scanin seed using the scanin seed setter and resetting the monitor using the monitor resetter;
generating the random shift patterns using the random shift pattern generator;
resetting the monitor a second time using the monitor resetter;
generating the random shift patterns a second time using the random shift pattern generator;
strobing an activity flag using the activity flag strober;
resetting the monitor a third time using the monitor resetter and enabling the scan enable signal toggling mechanism using the enabler; and
generating random shift/capture patterns repeatedly at least a predetermined number of times using the random shift/capture pattern generator.
